(19) United States
(12) Patent Application Publication
(10) Pub. No.: US 2024/0284717 A1
(43) Pub. Date: Aug. 22, 2024

(54) COLOR CONVERSION SUBSTRATE AND DISPLAY DEVICE INCLUDING THE SAME

(71) Applicant: Samsung Display Co., Ltd., Yongin-si (KR)

(72) Inventor: SANGHYUNG LIM, Yongin-si (KR)

(21) Appl. No.: 18/510,459

(22) Filed: Nov. 15, 2023

(30) Foreign Application Priority Data
Feb. 22, 2023 (KR) 10-2023-0023954

(51) Int. Cl. H10K 59/122; H10K 59/38; H10K 59/80

(52) U.S. Cl. CPC H10K 59/122; H10K 59/38; H10K 59/8723; H10K 59/8792

(57) ABSTRACT

A color conversion substrate includes a bank defining a main opening area including a first color conversion opening, a second color conversion opening, and a third color conversion opening, and defining a sub opening area including an auxiliary opening, a color conversion layer in the first, second, and third color conversion openings, and including color conversion particles, a dam structure in the auxiliary opening, and defining a dam opening, a first spacer above the bank, having a closed loop shape, and surrounding the first color conversion opening, the second color conversion opening, and the third color conversion opening in plan view, and a second spacer above the bank, having a closed loop shape, and surrounding the first spacer in plan view.

### CROSS-REFERENCE TO RELATED APPLICATION

This application claims priority to, and the benefit of, Korean Patent Application No. 10-2023-0023954, filed on Feb. 22, 2023, the content of which in its entirety is herein incorporated by reference.

### BACKGROUND

### 1. Field

The disclosure relates to a color conversion substrate, and a display device including the color conversion substrate.

### 2. Description of the Related Art

A flat panel display device is used as a display device replacing a cathode ray, and due to characteristics, such as light weight and thin shape. Representative examples of such flat panel display devices include a liquid crystal device (LCD) and an organic light-emitting display device (OLED).

Recently, an organic light-emitting element including an organic light-emitting element and a color conversion layer has been studied. The color conversion layer may convert a wavelength of light provided from the light-emitting device. Accordingly, light having a color different from a color of incident light may be emitted.

### SUMMARY

Embodiments provide a color conversion substrate with improved display characteristics.

Embodiments provide a display device with improved display characteristics.

A color conversion substrate according to one or more embodiments may include a bank defining a main opening area including a first color conversion opening, a second color conversion opening, and a third color conversion opening, and defining a sub opening area including an auxiliary opening, a color conversion layer in the first, second, and third color conversion openings, and including color conversion particles, a dam structure in the auxiliary opening, and defining a dam opening, a first spacer above the bank, having a closed loop shape, and surrounding the first color conversion opening, the second color conversion opening, and the third color conversion opening in plan view, and a second spacer above the bank, having a closed loop shape, and surrounding the first spacer in plan view.

The first spacer and the second spacer may include a same material.

The dam structure and the bank may include a same material.

The dam structure may have a closed loop shape.

A side surface of the dam structure and a side surface of the bank may define a first valley part surrounding the dam opening in plan view.

A side surface of the first spacer and a side surface of the second spacer may define a second valley part in plan view.

The first spacer may surround each of the first color conversion opening, the second color conversion opening, and the third color conversion opening in plan view, wherein the second valley part surrounds each of the first color conversion opening, the second color conversion opening, and the third color conversion opening in plan view.

The first spacer may surround the main opening area in plan view, wherein the second valley part surrounds the main opening area in plan view.

The bank may include an active area including the main opening area, wherein the first spacer surrounds the active area in plan view, and wherein the second valley part surrounds the active area in plan view.

The color conversion layer may include a first color conversion part, a second color conversion part, and a light transmission part in the first, second, and third color conversion openings, respectively.

A display device according to one or more embodiments may include a bank defining a main opening area including a first color conversion opening, a second color conversion opening, and a third color conversion opening, and defining a sub opening area including an auxiliary opening, a color conversion layer in the first, second, and third color conversion openings, and including color conversion particles, a dam structure in the auxiliary opening, and defining a dam opening, a first spacer above the bank, having a closed loop shape, and surrounding the first color conversion opening, the second color conversion opening, and the third color conversion opening in plan view, a second spacer above the bank, having a closed loop shape, and surrounding the first spacer, an array substrate below the color conversion layer, and including light-emitting elements overlapping the first, second, and third color conversion openings, respectively, and a filling layer above the array substrate, and spaced apart from the first, second, and third color conversion openings in a plan view.

The filling layer may be spaced apart from the color conversion layer in plan view.

At least a portion of the filling layer may be in the dam opening.

A side surface of the dam structure and a side surface of the bank may define a first valley part, wherein at least a portion of the filling layer is in the first valley part.

A side surface of the first spacer and a side surface of the second spacer may define a second valley part, wherein at least a portion of the filling layer is in the second valley part.

The first spacer may surround each of the first color conversion opening, the second color conversion opening, and the third color conversion opening in plan view, wherein the filling layer surrounds each of the first color conversion opening, the second color conversion opening, and the third color conversion opening in plan view.

The first spacer may surround the main opening area in plan view, wherein the filling layer surrounds the main opening area in plan view.

The bank may include an active area including the main opening area, wherein the first spacer surrounds the active area in plan view, and wherein the filling layer surrounds the active area in plan view.

The filling layer may include a light-blocking material.

The first color conversion opening and the third color conversion opening may be repeatedly arranged in a first row, wherein the second color conversion opening is repeatedly arranged in a second row, and wherein the sub opening area is between the first, second, and third color conversion openings.

The display device according to embodiments may include an array substrate and a color conversion substrate located on the array substrate. In addition, the color conversion substrate may include a bank including a main opening area including first to third color conversion openings, and a sub opening area including auxiliary openings. In addition, the color conversion substrate may include a dam structure defining a dam opening and located in the auxiliary opening, a first spacer located on the bank and surrounding the first to third color conversion openings, and a second spacer located on the bank and surrounding the first spacer.

Accordingly, in the color conversion substrate, a first valley part may be defined from a side surface of the dam structure and a side surface of the bank, and a second valley part may be defined from a side surface of the first spacer and a side surface of the second spacer.

Therefore, when a filling material is applied to form a filling layer between the array substrate and the color conversion substrate, the dam structure, the first spacer, and the second spacer may reduce or prevent the likelihood of the filling material overflowing into the first to third color conversion openings, which are neighboring. In other words, the filling layer may be selectively located in the dam opening, the first valley part and/or the second valley part. Accordingly, the filling layer may be spaced apart from the first to third color conversion openings in a plan view. In other words, the filling layer may be spaced apart from the light-emitting area in a plan view.

Accordingly, a phenomenon in which spots are generated in a light-emitting area due to scattering of the filling layer may be reduced or prevented. Also, because the light emitted from the array substrate does not pass through the filling layer, luminous efficiency of the display device may be improved. Accordingly, display characteristics of the display device may be improved.

It is to be understood that both the foregoing general description and the following detailed description are merely examples, and are intended to provide further explanation of the present disclosure.

### BRIEF DESCRIPTION OF THE DRAWINGS

Illustrative, non-limiting embodiments will be more clearly understood from the following detailed description taken in conjunction with the accompanying drawings.

FIG. 1 is a perspective view illustrating a display device according to one or more embodiments.

FIG. 2 is a cross-sectional view taken along the line I-I′ of FIG. 1.

FIG. 3 is a plan view illustrating the display device of FIG. 1.

FIG. 4 is a plan view illustrating a color conversion substrate included in the display device of FIG. 1 according to one or more embodiments.

FIG. 5 is an enlarged view illustrating an enlarged area A of FIG. 4.

FIG. 6 is a cross-sectional view taken along the line II-II′ of FIG. 3.

FIGS. 7 to 9 are cross-sectional views illustrating display devices according to other embodiments.

FIG. 10 is a plan view illustrating a display device according to one or more other embodiments.

FIG. 11 is a plan view illustrating a color conversion substrate included in the display device of FIG. 10.

FIG. 12 is an enlarged view illustrating an enlarged area B of FIG. 11.

FIG. 13 is a cross-sectional view taken along the line III-III′ of FIG. 10.

FIG. 14 is a plan view illustrating a display device according to still one or more other embodiments of the present disclosure.

FIG. 15 is a plan view illustrating a color conversion substrate included in the display device of FIG. 14.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

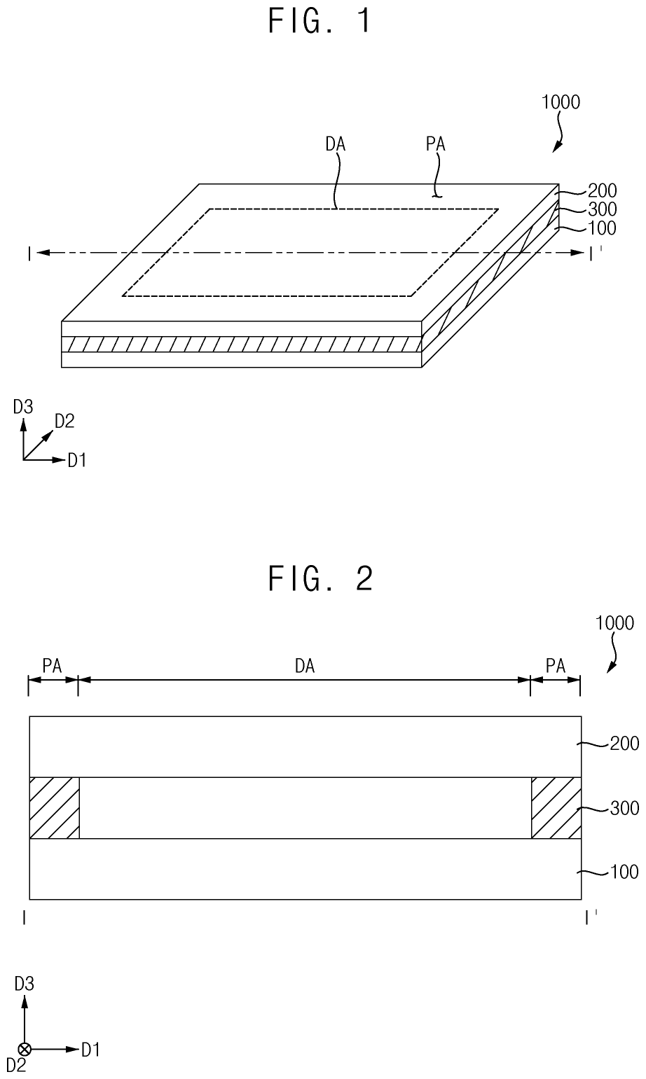

FIG. 1 is a perspective view illustrating a display device according to one or more embodiments. FIG. 2 is a cross-sectional view taken along the line I-I′ of FIG. 1.

Referring to FIGS. 1 and 2, the display device 1000 may include an array substrate 100, a color conversion substrate 200, and a sealing member 300.

The display device 1000 may have a rectangular planar shape. For example, the display device 1000 may include two first sides extending in a first direction D1, and two second sides extending in a second direction D2 that is perpendicular to the first direction D1. A corner where the first side and the second side meet may be a right angle. In one or more other embodiments, a corner where the first side and the second side meet may form a curved surface. A third direction D3 is a front direction of the display device 1000, and may be a direction that is normal to a plane defined by the first and second directions D1 and D2. That is, the display device 1000 may display an image in the third direction D3.

The display device 1000 may be divided into a display area DA and a peripheral area PA. In one or more embodiments, the display area DA may display an image, and the peripheral area PA may not display an image. The peripheral area PA may be located around the display area DA. For example, the peripheral area PA may surround the display area DA (e.g., in plan view).

The array substrate 100 may include a substrate, an insulating structure, and an element for displaying an image. For example, the element may include a driving element, a light-emitting element, or the like. A detailed description of the array substrate 100 will be described later.

The color conversion substrate 200 may be located on the array substrate 100. The color conversion substrate 200 may face the array substrate 100. The color conversion substrate 200 may include a color conversion layer, which converts a wavelength of light emitted from the light-emitting element. A detailed description of the color conversion substrate 200 will be described later.

The sealing member 300 may be located between the array substrate 100 and the color conversion substrate 200 in the peripheral area PA. The sealing member 300 may be located along edges of the array substrate 100 and the color conversion substrate 200 in the peripheral area PA to surround the display area DA in a plan view. In addition, the array substrate 100 and the color conversion substrate 200 may be bonded through the sealing member 300. The sealing member 300 may include an organic material. For example, the sealing member 300 may include an epoxy resin or the like.

The display device 1000 may be an organic light-emitting display device (OLED), a liquid crystal display device (LCD), a field emission display device (FED), a plasma display device (PDP), or an electrophoretic display device (EPD). Hereinafter, for convenience of description, an example in which the display device 1000 is an organic light-emitting display device will be described.

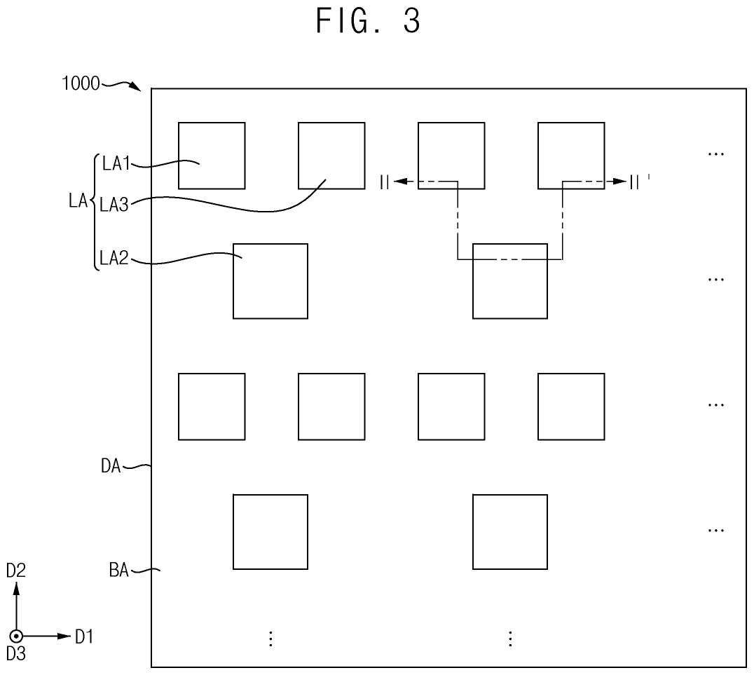

FIG. 3 is a plan view illustrating the display device of FIG. 1.

Referring to FIG. 3, the display area DA of the display device 1000 may include a light-emitting area LA and a light-blocking area BA. Here, the light-emitting area LA may include a first light-emitting area LA1, a second light-emitting area LA2, and a third light-emitting area LA3.

Each of the first to third light-emitting areas LA1, LA2, and LA3 may be an area where light emitted from the light-emitting element is emitted to outside of the display device 1000. For example, the first light-emitting area LA1 may emit first light, the second light-emitting area LA2 may emit second light, and the third light-emitting area LA3 may emit third light. For example, the first light may be red light, the second light may be green light, and the third light may be blue light. However, the present disclosure is not necessarily limited thereto.

In a plan view, each of the first to third light-emitting areas LA1, LA2, and LA3 may be repeatedly arranged along a row direction and a column direction. For example, in a plan view, each of the first to third light-emitting areas LA1, LA2, and LA3 may be repeatedly arranged along the first direction D1 and the second direction D2. In one or more embodiments, in a plan view, the first light-emitting area LA1 and the third light-emitting area LA3 may be repeatedly arranged in a first row of the display area DA, and the second light-emitting area LA2 may be repeatedly arranged in a second row of the display area DA.

In one or more embodiments, each of the first to third light-emitting areas LA1, LA2, and LA3 may have different areas. In one or more embodiments, an area of the first light-emitting area LA1 may be equal to an area of the third light-emitting area LA3, and an area of the second light-emitting area LA2 may be larger than each of the area of the first light-emitting area LA1 and the area of the third light-emitting area LA3. In one or more other embodiments, the area of the second light-emitting area LA2 may be larger than the area of the first light-emitting area LA1, and the area of the first light-emitting area LA1 may be larger than the area of the third light-emitting area LA3. However, the present disclosure is not necessarily limited thereto, and each of the first to third light-emitting areas LA1, LA2, and LA3 may have a same area.

In one or more embodiments, each of the first to third light-emitting areas LA1, LA2, and LA3 may have a quadrangular planar shape. However, the present disclosure is not necessarily limited thereto, and each of the first to third light-emitting areas LA1, LA2, and LA3 may have a polygonal planar shape, rather than a quadrangular planar shape, a circular planar shape, a track-shaped planar shape, an elliptical planar shape, or the like.

The light-blocking area BA may be located between the first light-emitting area LA1, the second light-emitting area LA2, and the third light-emitting area LA3. For example, in a plan view, the light-blocking area BA may surround the first light-emitting area LA1, the second light-emitting area LA2, and the third light-emitting area LA3. The light-blocking area BA may not emit light.

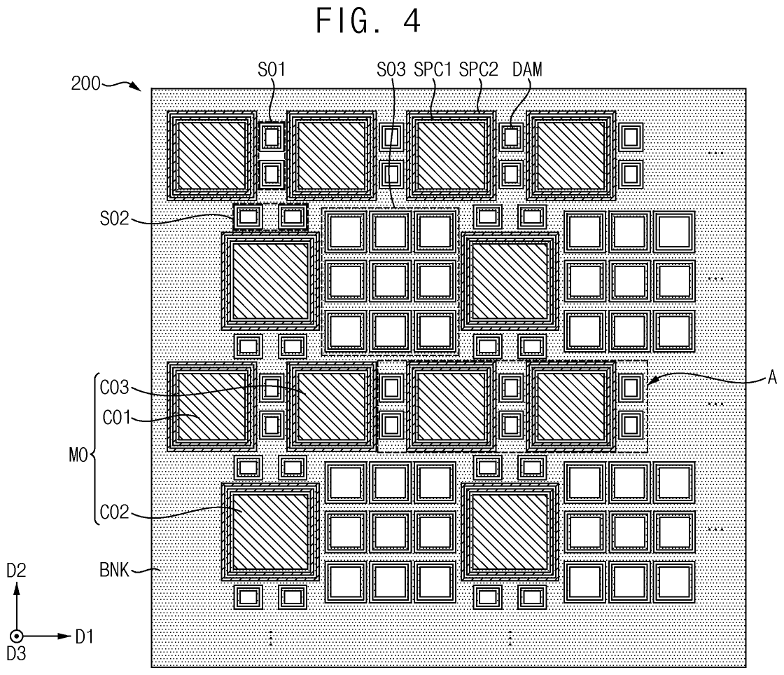

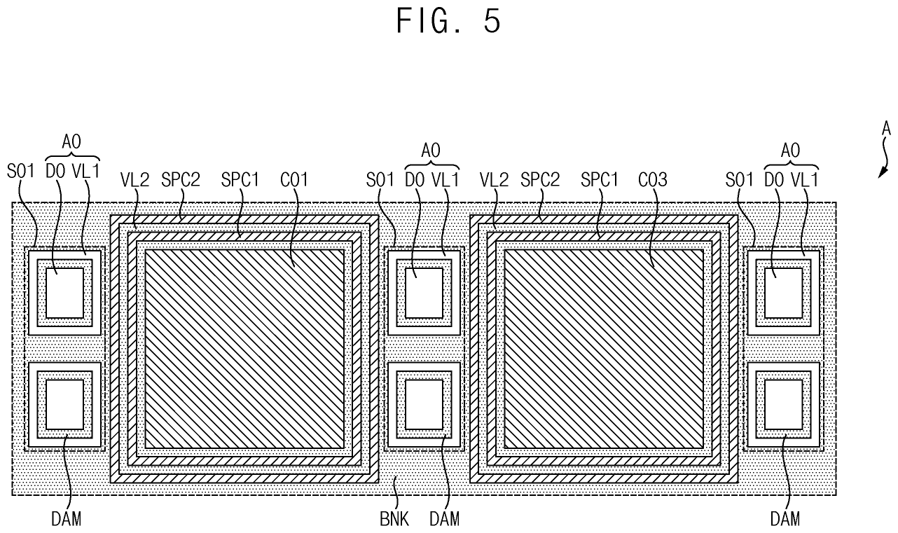

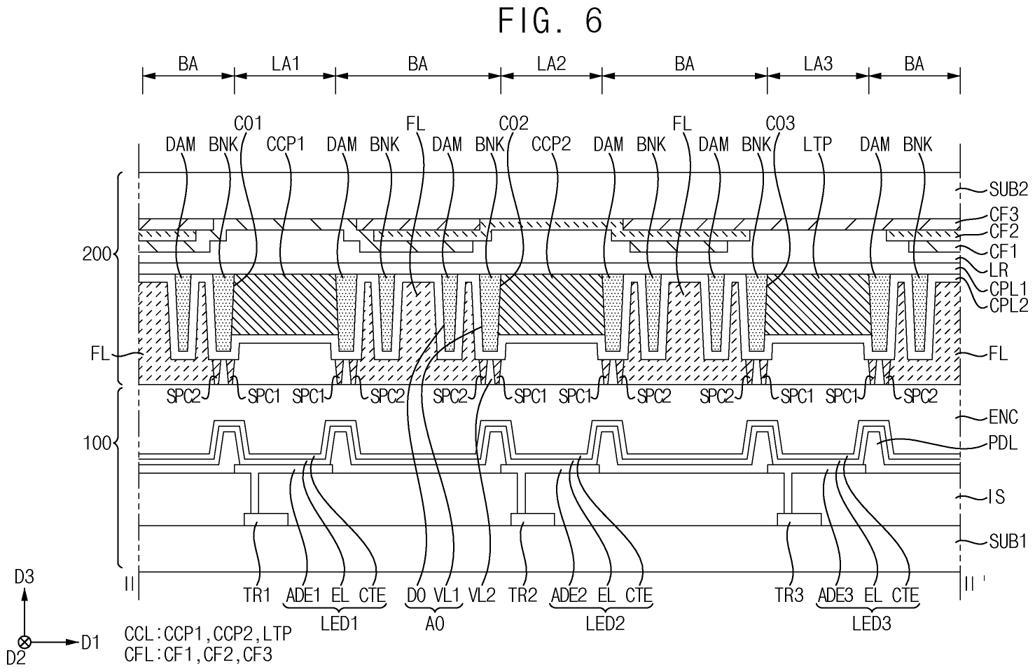

FIG. 4 is a plan view illustrating a color conversion substrate included in the display device of FIG. 1 according to one or more embodiments. FIG. 5 is an enlarged view illustrating an enlarged area A of FIG. 4. FIG. 6 is a cross-sectional view taken along the line II-II′ of FIG. 3.

Referring to FIGS. 1 to 6, the display device 1000 may include the array substrate 100, the color conversion substrate 200, and a filling layer FL. First, the array substrate 100 will be described.

The array substrate 100 may include a first substrate SUB1, first to third driving elements TR1, TR2, and TR3, an insulating structure IS, a pixel-defining layer PDL, first to third light-emitting elements LED1, LED2, and LED3, and an encapsulation layer ENC.

The first substrate SUB1 may be an insulating substrate formed of a transparent or opaque material. In one or more embodiments, the first substrate SUB1 may include glass. In this case, the array substrate 100 may be a rigid array substrate. In one or more other embodiments, the first substrate SUB1 may include plastic. In this case, the array substrate 100 may be a flexible array substrate.

The first to third driving elements TR1, TR2, and TR3 may be located in the display area DA on the first substrate SUB1. Each of the first to third driving elements TR1, TR2, and TR3 may include at least one thin film transistor. A channel layer of the thin film transistor may include an oxide semiconductor, a silicon semiconductor, or an organic semiconductor. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), zinc (Zn), or the like. The silicon semiconductor may include amorphous silicon, polycrystalline silicon, or the like.

The insulating structure IS may cover the first to third driving elements TR1, TR2, and TR3. The insulating structure IS may include a combination of an inorganic insulating layer and an organic insulating layer.

First to third pixel electrodes ADE1, ADE2, and ADE3 may be located on the insulating structure IS. Each of the first to third pixel electrodes ADE1, ADE2, and ADE3 may include a conductive material, such as a metal, an alloy, a conductive metal nitride, a conductive metal oxide, or a transparent conductive material. Each of the first to third pixel electrodes ADE1, ADE2, and ADE3 may have a single-layer structure or a multi-layer structure including a plurality of conductive layers.

The first to third pixel electrodes ADE1, ADE2, and ADE3 may be respectively electrically connected to the first to third driving elements TR1, TR2, and TR3 through contact holes formed in the insulating structure IS, respectively.

The pixel-defining layer PDL may be located on the first to third pixel electrodes ADE1, ADE2, and ADE3. The pixel-defining layer PDL may include an organic insulating material. Examples of the organic insulating material may include photoresist, polyacryl-based resin, polyimide-based resin, polyamide-based resin, siloxane-based resin, acrylic-based resin, epoxy-based resin, or the like. These may be used alone or in combination with each other. The pixel-defining layer PDL may define a pixel opening exposing at least a portion of each of the first to third pixel electrodes ADE1, ADE2, and ADE3.

An emission layer EL may be located on the first to third pixel electrodes ADE1, ADE2, and ADE3 exposed by the pixel opening of the pixel-defining layer PDL. In one or more embodiments, the emission layer EL may continuously extend over a plurality of pixels and on the display area DA. In one or more other embodiments, the emission layer EL may be separated from an emission layer of an adjacent pixel.

The emission layer EL may include an organic light-emitting material. In one or more embodiments, the emission layer EL may generate blue light. However, the present disclosure is not necessarily limited thereto, and the emission layer EL may generate red light or green light or may generate lights having different colors according to pixels.

In one or more embodiments, functional layers, such as a hole injection layer, a hole transport layer, an electron transport layer, and an electron injection layer may be located above and/or below the emission layer EL.

A common electrode CTE may be located on the emission layer EL. The common electrode CTE may include a conductive material, such as a metal, an alloy, a conductive metal nitride, a conductive metal oxide, or a transparent conductive material. The common electrode CTE may have a single-layer structure or a multi-layer structure including a plurality of conductive layers. In one or more embodiments, the common electrode CTE may continuously extend over a plurality of pixels and on the display area DA.

The first pixel electrode ADE1, the emission layer EL, and the common electrode CTE may form the first light-emitting element LED1, the second pixel electrode ADE2. The emission layer EL, and the common electrode CTE may form the second light-emitting element LED2. The third pixel electrode ADE3, the emission layer EL, and the common electrode CTE may form the third light-emitting element LED3.

The first light-emitting element LED1 may be located in the first light-emitting area LA1. The second light-emitting element LED2 may be located in the second light-emitting area LA2. The third light-emitting element LED3 may be located in the third light-emitting area LA3.

The encapsulation layer ENC may be located on the common electrode CTE. The encapsulation layer ENC may include at least one inorganic encapsulation layer and at least one organic encapsulation layer. In one or more embodiments, the encapsulation layer ENC may include a first inorganic encapsulation layer located on the common electrode CTE, an organic encapsulation layer located on the first inorganic encapsulation layer, and a second inorganic encapsulation layer located on the organic encapsulation layer.

Hereinafter, the color conversion substrate 200 will be described. The color conversion substrate 200 may include a second substrate SUB2, a color filter layer CFL, a refraction layer LR, a first capping layer CPL1, a bank BNK, a color conversion layer CCL, a dam structure DAM, a second capping layer CPL2, a first spacer SPC1, and a second spacer SPC2.

The second substrate SUB2 may be an insulating substrate formed of a transparent or opaque material. In one or more embodiments, the second substrate SUB2 may include glass. In this case, the color conversion substrate 200 may be a rigid color conversion substrate. In one or more other embodiments, the second substrate SUB2 may include plastic. In this case, the color conversion substrate 200 may be a flexible color conversion substrate.

The color filter layer CFL may be located below the second substrate SUB2. In one or more embodiments, the color filter layer CFL may include a first color filter CF1, a second color filter CF2, and a third color filter CF3. For example, the first color filter CF1 may be a red color filter that selectively transmits red light, the second color filter CF2 may be a green color filter that selectively transmits green light, and the third color filter CF3 may be a blue color filter that selectively transmits blue light. However, the present disclosure is not necessarily limited thereto.

In one or more embodiments, at least a portion of the first color filter CF1 may overlap the first light-emitting area LA1, and at least a portion of the second color filter CF2 may overlap the second light-emitting area LA2, and at least a portion of the third color filter CF3 may overlap the third light-emitting area LA3.

In one or more embodiments, each of the first color filter CF1, the second color filter CF2, and the third color filter CF3 may be located to overlap with the light-blocking area BA to a greater extent. That is, as shown in FIG. 6, the first color filter CF1 may overlap the first light-emitting area LA1 and the light-blocking area BA, while not overlapping the second light-emitting area LA2 and the third light-emitting area LA3. The second color filter CF2 may overlap the second light-emitting area LA2 and the light-blocking area BA, while not overlapping the first light-emitting area LA1 and the third light-emitting area LA3. The third color filter CF3 may overlap the third light-emitting area LA3 and the light-blocking area BA, while not overlapping the first light-emitting area LA1 and the second light-emitting area LA2. In this case, in the blocking area BA, a portion of each of the first to third color filters CF1, CF2, and CF3 may overlap each other in the third direction D3. Accordingly, color mixing between the first to third light-emitting areas LA1, LA2, and LA3, which are adjacent, may be reduced or prevented.

The refraction layer LR may be located below the color filter layer CFL. For example, the refraction layer LR may cover the color filter layer CFL. The refractive layer LR may have a relatively low refractive index. For example, a refractive index of the refractive layer LR may be lower than a refractive index of the color conversion layer CCL. The refractive layer LR may include an organic material. For example, the refractive layer LR may include an organic polymer material including silicon.

The first capping layer CPL1 may be located below the refraction layer LR. For example, the first capping layer CPL1 may cover, or overlap, the refractive layer LR. The first capping layer CPL1 may block external impurities to reduce or prevent contamination of the color filter layer CFL. The first capping layer CPL1 may include an inorganic material. For example, the first capping layer CPL1 may include silicon oxide, silicon nitride, aluminum nitride, or the like.

The bank BNK may be located below the first capping layer CPL1. The bank BNK may overlap the light-blocking area BA. The bank BNK may form a space capable of accommodating ink composition in a process of forming the color conversion layer CCL.

In one or more embodiments, the bank BNK may include an organic material. In one or more embodiments, the bank BNK may further include a light-blocking material. For example, the bank BNK may include a light-blocking material, such as black pigment, black dye, or carbon black.

As shown in FIG. 4, the bank BNK may include a main opening area MO and first to third sub opening areas SO1, SO2, and SO3. Here, the main opening area MO may refer to a portion filled with a material of the color conversion layer CCL among spaces formed by the bank BNK, and the first to third sub opening areas SO1, SO2, and SO3 may refer to a portion not filled with the material of the color conversion layer CCL among the spaces formed by the bank BNK.

The main opening area MO may include first to third color conversion openings CO1, CO2, and CO3. That is, the color conversion layer CCL may be formed in the first to third color conversion openings CO1, CO2, and CO3 by an inkjet method.

In one or more embodiments, the first color conversion opening CO1 may overlap the first light-emitting area LA1, the second color conversion opening CO2 may overlap the second light-emitting area LA2, and the third color conversion opening CO3 may overlap the third light-emitting area LA3.

For example, as shown in FIG. 4, each of the first to third color conversion openings CO1, CO2, and CO3 may be repeatedly arranged along the row direction and the column direction in a plan view. For example, in a plan view, each of the first to third color conversion openings CO1, CO2, and CO3 may be repeatedly arranged along the first direction D1 and the second direction D2. In one or more embodiments, in a plan view, the first and third color conversion openings CO1 and CO3 may be repeatedly arranged in a first row and a third row, and the second color conversion opening CO2 may be repeatedly arranged in a second row and a fourth row.

In one or more embodiments, each of the first to third sub opening areas SO1, SO2, and SO3 may include auxiliary openings AO. Each of the first to third sub opening areas SO1, SO2, and SO3 may be located between the first to third color conversion openings CO1, CO2, and CO3, which are neighboring.

In one or more embodiments, each of the first to third sub opening areas SO1, SO2, and SO3 may overlap at least a portion of the light-blocking area BA.

For example, in a plan view, the first sub opening area SO1 may be repeatedly arranged in the first row and the third row with the first color conversion opening CO1 and the third color conversion opening CO3 interposed therebetween. The second sub opening area SO2 may be repeatedly arranged along the first direction D1, with the first and second color conversion openings CO1 and CO2 and the third color conversion opening CO3 interposed therebetween in the second direction D2. The third sub opening area SO3 may be repeatedly arranged in the second row and the fourth row along the second direction D2 with the second color conversion opening CO2 interposed therebetween in the first direction.

Each of the first to third sub opening areas SO1, SO2, and SO3 may reduce or prevent the likelihood of the material of the color conversion layer CCL being lost to neighboring color conversion openings.

Meanwhile, although the bank BNK is illustrated as including first to third sub open areas SO1, SO2, and SO3 in FIG. 4, the present disclosure is not necessarily limited thereto. For example, the bank BNK may include two or fewer sub opening areas or four or more sub opening areas.

In addition, the first and second sub opening areas SO1 and SO2 each include two auxiliary openings AO, and the third sub opening area SO3 includes nine auxiliary openings AO in FIG. 4, however, the present disclosure is not necessarily limited thereto. For example, each of the first and second sub opening areas SO1 and SO2 may include one auxiliary opening or three or more auxiliary openings, and the third sub opening area SO3 may include eight or fewer auxiliary openings or ten or more auxiliary openings.

In addition, although each of the first to third color conversion openings CO1, CO2, and CO3 and the auxiliary openings AO is illustrated as having a quadrangular planar shape in FIG. 4, the present disclosure is not necessarily limited thereto. For example, each of the first to third color conversion openings CO1, CO2, and CO3 and the auxiliary openings AO may have a polygonal planar shape other than a quadrangular shape, a circular planar shape, a track-shaped planar shape, or an elliptical planar shape, or the like.

The color conversion layer CCL may be located below the first capping layer CPL1. The color conversion layer CCL may include a first color conversion part CCP1, a second color conversion part CCP2, and a light transmission part LTP. For example, the first color conversion part CCP1 may be located in the first color conversion opening CO1, the second color conversion part CCP2 may be located in the second color conversion opening CO2, and the light transmission part LTP may be located in the third color conversion opening CO3.

The first color conversion part CCP1 may convert light emitted from the first light-emitting element LED1 into light of a first color (e.g., red light). The second color conversion part CCP2 may convert light emitted from the second light-emitting element LED2 into light of a second color (e.g., green light). The light transmission part LTP may transmit light emitted from the third light-emitting element LED3. In one or more embodiments, light emitted from the first to third light-emitting elements LED1, LED2, and LED3 may be blue light. However, the present disclosure is not necessarily limited thereto, and the light may mean light of other colors, such as white light.

The first color conversion part CCP1 may include first color conversion particles excited by the light generated from the first light-emitting element LED1, and may emit light of the first color. The first color conversion part CCP1 may further include a first photosensitive polymer in which first scattering particles are dispersed.

The second color conversion part CCP2 may include second color conversion particles excited by the light generated from the second light-emitting element LED2, and may emit light of the second color. The second color conversion part CCP2 may further include a second photosensitive polymer in which second scattering particles are dispersed. Each of the first color conversion particles and the second color conversion particles may mean a quantum dot.

The light transmission part LTP may transmit the light generated from the third light-emitting element LED3, and may emit the light in the third direction D3. The light transmission part LTP may include a third photosensitive polymer in which third scattering particles are dispersed. For example, each of the first to third photosensitive polymers may include a light-transmitting organic material, such as a silicone resin or an epoxy resin. The first to third photosensitive polymers may include a same material as each other. The first to third scattering particles may scatter, and may emit light generated from the first to third light-emitting elements LED1, LED2, and LED3, and the first to third scattering particles may include a same material as each other.

The dam structure DAM may be located below the first capping layer CPL1, and may be inside at least one of the auxiliary openings AO.

The dam structure DAM may be spaced apart from the first to third light-emitting areas LA1, LA2, and LA3 in a plan view. For example, the dam structure DAM may overlap at least a portion of the light-blocking area BA in a plan view.

In one or more embodiments, the dam structure DAM may have a ring shape (e.g., a closed loop shape). Accordingly, as shown in FIG. 5, each of the auxiliary openings AO in which the dam structure DAM is located may be divided into a dam opening DO and a first valley part VL1. The dam opening DO may be defined from an inner side surface of the dam structure DAM. The first valley part VL1 may be defined from a side surface of the dam structure DAM and a side surface of the bank BNK. For example, the first valley part VL1 may be defined from an outer surface of the dam structure DAM, and an inner surface of the bank BNK that is adjacent to the outer surface of the dam structure DAM.

In one or more embodiments, the dam structure DAM may be formed together with the bank BNK in a same process. For example, the dam structure DAM may include a same material as the bank BNK. For example, the dam structure DAM may include an organic material. In one or more embodiments, the dam structure DAM may further include a light-blocking material. For example, the dam structure DAM may further include a light-blocking material, such as black pigment, black dye, or carbon black.

Meanwhile, in FIG. 4, the dam structure DAM is shown to be located inside each of the auxiliary openings AO, but the present disclosure is not necessarily limited thereto. For example, the dam structure DAM may be located inside some of the auxiliary openings AO while not being located inside others of the auxiliary openings AO.

The second capping layer CPL2 may be located below the first capping layer CPL1, the bank BNK, the color conversion layer CCL, and the dam structure DAM. For example, the second capping layer CPL2 may cover the first capping layer CPL1, the bank BNK, the color conversion layer CCL, and the dam structure DAM. In one or more embodiments, the second capping layer CPL2 may include an inorganic material.

The first spacer SPC1 may be located on the bank BNK. For example, the first spacer SPC1 may be spaced apart from the first to third light-emitting areas LA1, LA2, and LA3 in a plan view. For example, the first spacer SPC1 may overlap at least a portion of the light-blocking area BA in a plan view.

The first spacer SPC1 may have a ring shape (e.g., a closed loop shape, which may have a square perimeter). Accordingly, the first spacer SPC1 may surround (e.g., in plan view) the first color conversion opening CO1, the second color conversion opening CO2, and the third color conversion opening CO3.

In one or more embodiments, the first spacer SPC1 may surround (e.g., in plan view) each of the first color conversion opening CO1, the second color conversion opening CO2, and the third color conversion opening CO3.

For example, as shown in FIG. 4, in a plan view, the first spacer SPC1 may be repeatedly arranged along the row direction and the column direction. For example, in a plan view, the first spacer SPC1 may be repeatedly arranged along the first direction D1 and the second direction D2. In one or more embodiments, in a plan view, the first spacer SPC1 surrounding the first and third color conversion openings CO1 and CO3 may be repeatedly arranged in the first row and the third row, and the first spacer SPC1 surrounding the color conversion opening CO2 may be repeatedly arranged in the second row and the fourth row.

In one or more embodiments, the first spacer SPC1 may include a polymer resin, and a pigment and/or dye dispersed in the polymer resin. For example, the first spacer SPC1 may include a light-blocking material, such as black pigment, black dye, or carbon black.

The second spacer SPC2 may be located on (e.g., may overlap) the bank BNK. For example, the second spacer SPC2 may be spaced apart from the first to third light-emitting areas LA1, LA2, and LA3 in a plan view. For example, the second spacer SPC2 may overlap at least a portion of the light-blocking area BA in a plan view.

The second spacer SPC2 may have a ring shape (e.g., a closed loop shape, with a square perimeter). Accordingly, the second spacer SPC2 may surround (e.g., in plan view) the first spacer SPC1. Accordingly, the second spacer SPC2 may surround (e.g., in plan view) the first color conversion opening CO1, the second color conversion opening CO2, and the third color conversion opening CO3.

In one or more embodiments, the second spacer SPC2 may surround (e.g., in plan view) each of the first color conversion opening CO1, the second color conversion opening CO2, and the third color conversion opening CO3.

For example, as shown in FIG. 4, in a plan view, the second spacer SPC2 may be repeatedly arranged along the row direction and the column direction. For example, in a plan view, the second spacer SPC2 may be repeatedly arranged along the first direction D1 and the second direction D2. In one or more embodiments, in a plan view, the second spacer SPC2 surrounding the first and third color conversion openings CO1 and CO3 may be repeatedly arranged in the first row and the third row, and the second spacer SPC2 surrounding the color conversion opening CO2 may be repeatedly arranged in the second row and the fourth row.

A side surface of the first spacer SPC1 and a side surface of the second spacer SPC2 may define a second valley part VL2. For example, an outer surface of the first spacer SPC1 and an inner surface of the second spacer SPC2 adjacent to the outer surface of the first spacer SPC1 may define the second valley part VL2.

In other words, the first spacer SPC1 and the second spacer SPC2 may define the second valley part VL2 having a ring shape, and the second valley part VL2 may surround the first color conversion opening CO1, the second color conversion opening CO2, and the third color conversion opening CO3.

For example, the second valley part VL2 may surround each of the first color conversion opening CO1, the second color conversion opening CO2, and the third color conversion opening CO3.

In one or more embodiments, the second spacer SPC2 and the first spacer SPC1 may be formed together in a same process. For example, the second spacer SPC2 may include a same material as the first spacer SPC1.

In one or more embodiments, the second spacer SPC2 may include a polymer resin, and a pigment and/or dye dispersed in the polymer resin. For example, the second spacer SPC2 may include a light-blocking material, such as black pigment, black dye, or carbon black.

Each of the first spacer SPC1 and the second spacer SPC2 may maintain a gap between the array substrate 100 and the color conversion substrate 200. Also, in a process of forming the filling layer FL, each of the first and second spacers SPC1 and SPC2 may reduce or prevent the likelihood of filling material overflowing to outside of each of the first and second spacers SPC1 and SPC2.

The filling layer FL may be located on the array substrate 100. For example, the filling layer FL may be located between the array substrate 100 and the second capping layer CPL2.

The filling layer FL may act as a buffer against external pressure applied to the display device 1000. For example, the filling layer FL may maintain a gap between the array substrate 100 and the color conversion substrate 200.

In one or more embodiments, the filling layer FL may include a filling material. For example, the filling layer FL may include an organic insulating material and/or an inorganic insulating material having relatively high light transmittance.

In one or more embodiments, the filling layer FL may be located in the auxiliary openings AO. For example, the filling layer FL may be located in the dam opening DO and in the first valley part VL1. For example, the filling layer FL may be formed by selectively applying the filling material into the dam opening DO and the first valley part VL1.

Meanwhile, the second spacer SPC2 may reduce or prevent the likelihood of the filling material overflowing into the first to third color conversion openings CO1, CO2, and CO3. In other words, the filling material may not be applied to the first to third light-emitting areas LA1, LA2, and LA3 by the second spacer SPC2.

Accordingly, the filling layer FL may be spaced apart from the first to third light-emitting areas LA1, LA2, and LA3 in a plan view, and may overlap at least a portion of the light-blocking area BA. In other words, the filling layer FL may not overlap the first to third light-emitting areas LA1, LA2, and LA3 in a plan view.

Accordingly, the filling layer FL may be spaced apart from the first to third color conversion openings CO1, CO2, and CO3 of the bank BNK in a plan view. For example, the filling layer FL may surround the first color conversion opening CO1, the second color conversion opening CO2, and the third color conversion opening CO3. That is, the filling layer FL may be spaced apart from the color conversion layer CCL in a plan view. In one or more embodiments, the filling layer FL may surround each of the first color conversion opening CO1, the second color conversion opening CO2, and the third color conversion opening CO3.

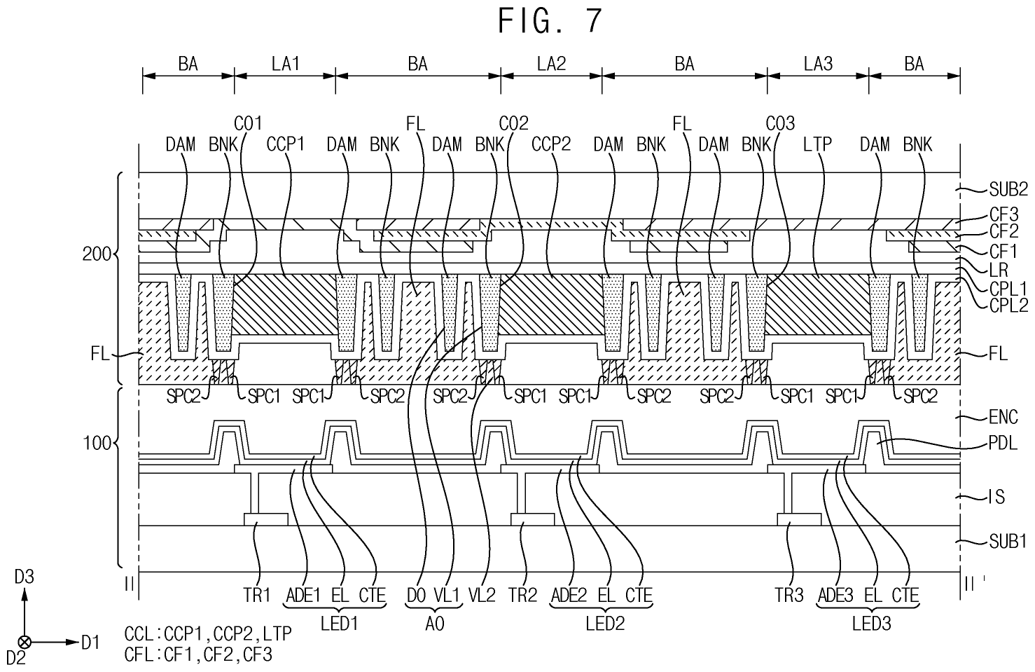

FIGS. 7 to 9 are cross-sectional views illustrating display devices according to other embodiments.

FIGS. 7 to 9 may correspond to the cross-sectional view of FIG. 6. Hereinafter, display devices according to other embodiments will be described with reference to FIGS. 7 to 9. In the following description, differences from the display device 1000 described with reference to FIGS. 1 to 6 will be mainly described, and overlapping descriptions will be omitted or simplified.

Referring to FIG. 7, in one or more embodiments, the filling layer FL may also be located in the second valley part VL2. That is, the filling layer FL may be located in the dam opening DO, in the first valley part VL1, and in the second valley part VL2. For example, the filling layer FL may be formed by selectively applying the filling material to the dam opening DO, to the first valley part VL1, and to the second valley part VL2.

In this case, the first spacer SPC1 may reduce or prevent the likelihood of the filling material overflowing into the first to third color conversion openings CO1, CO2, and CO3, which are neighboring. In other words, the filling material may not be applied to the first to third light-emitting areas LA1, LA2, and LA3 by the first spacer SPC1.

Accordingly, the filling layer FL may be spaced apart from the first to third light-emitting areas LA1, LA2, and LA3 in a plan view, and may overlap at least a portion of the light-blocking area BA. In other words, the filling layer FL may not overlap the first to third light-emitting areas LA1, LA2, and LA3 in a plan view.

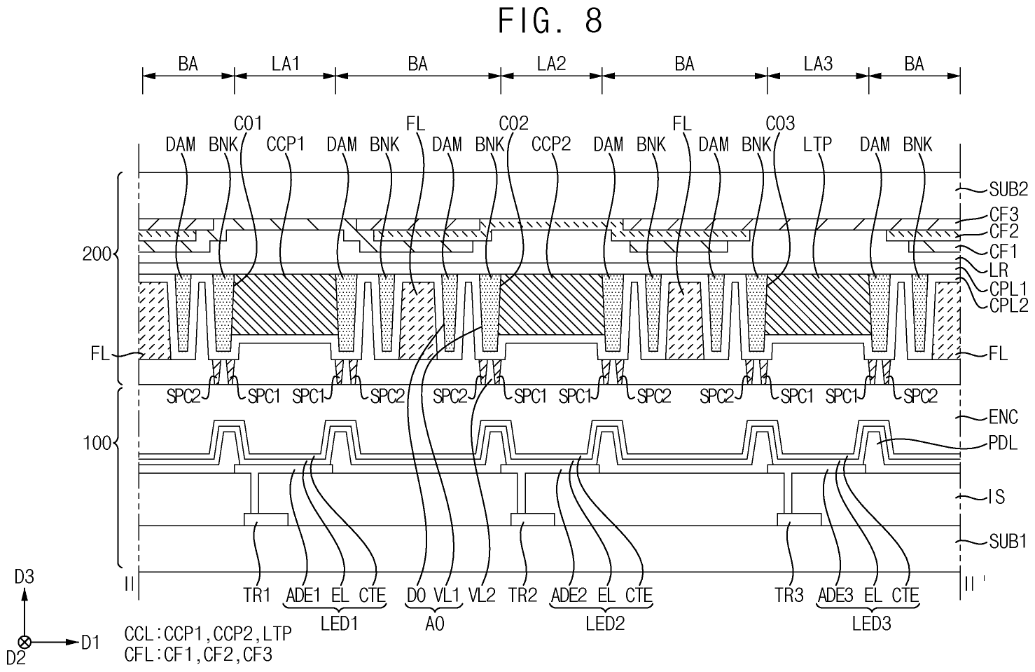

Referring to FIG. 8, in one or more embodiments, the filling layer FL may be located only in the dam opening DO. That is, the filling layer FL may not be located in the first valley part VL1 and the second valley part VL2. For example, the filling layer FL may be formed by selectively applying the filling material to the dam opening DO.

In this case, in the dam structure DAM may reduce or prevent the likelihood of the filling material overflowing into the first to third color conversion openings CO1, CO2, and CO3, the first valley part VL1, and the second valley part VL2, which are neighboring. In other words, the filling material may not be applied to the first to third light-emitting areas LA1, LA2, and LA3 by the dam structure DAM.

Accordingly, the filling layer FL may be spaced apart from the first to third light-emitting areas LA1, LA2, and LA3 in a plan view, and may overlap at least a portion of the light-blocking area BA. In other words, the filling layer FL may not overlap the first to third light-emitting areas LA1, LA2, and LA3 in a plan view.

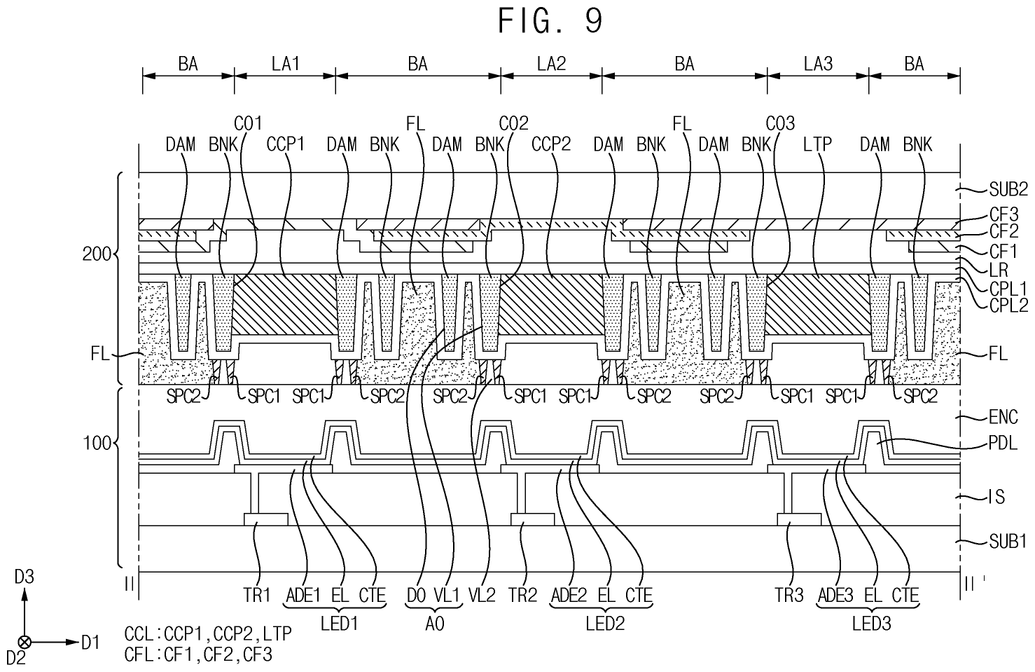

Referring to FIG. 9, in one or more embodiments, the filling layer FL may further include a light-blocking material. That is, the filling layer FL may include a light-blocking material, such as black pigment, black dye, or carbon black. Color mixing between the first to third light-emitting areas LA1, LA2, and LA3, which are adjacent, may be further reduced or prevented by the filling layer FL.

Meanwhile, even when the filling layer FL further includes a light-blocking material, as the filling layer FL does not overlap the first to third light-emitting areas LA1, LA2, and LA3 in a plan view, display characteristics of the display device 1000 may not degrade.

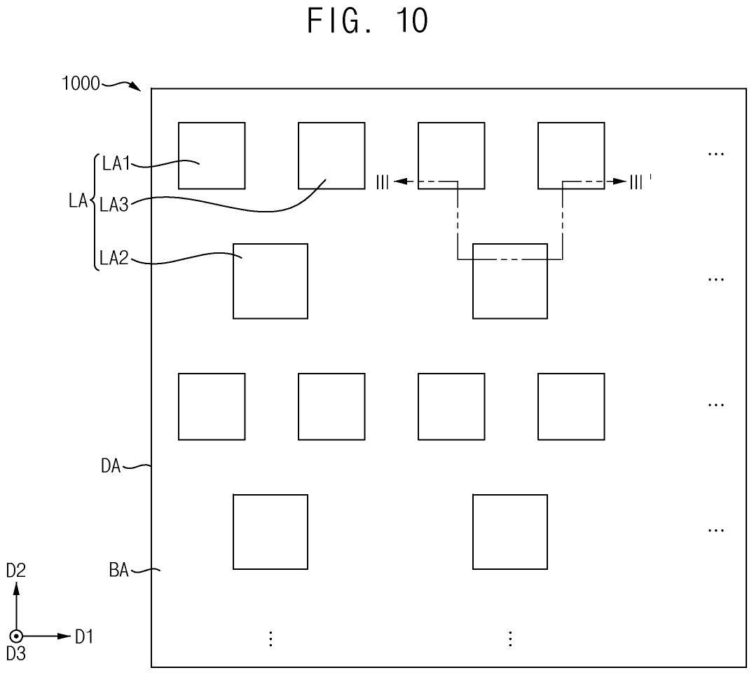

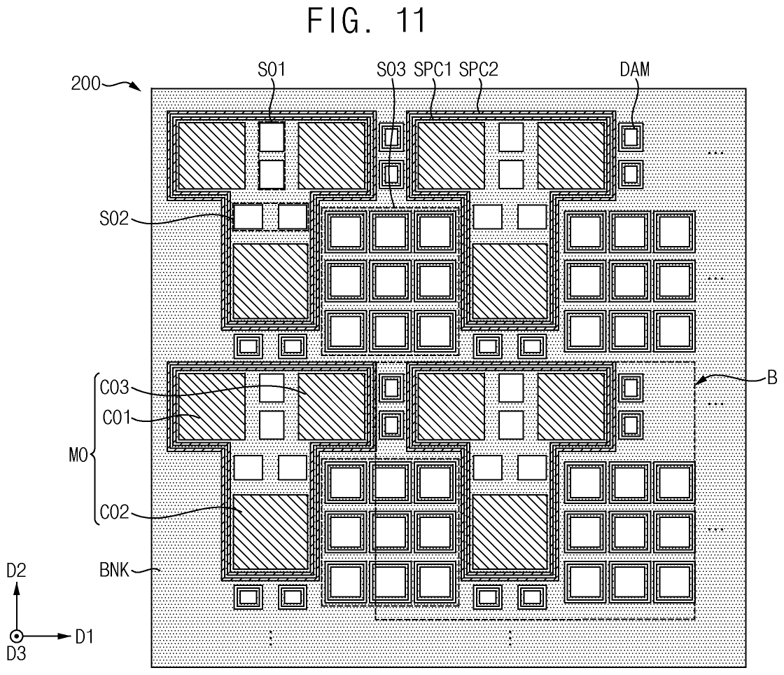

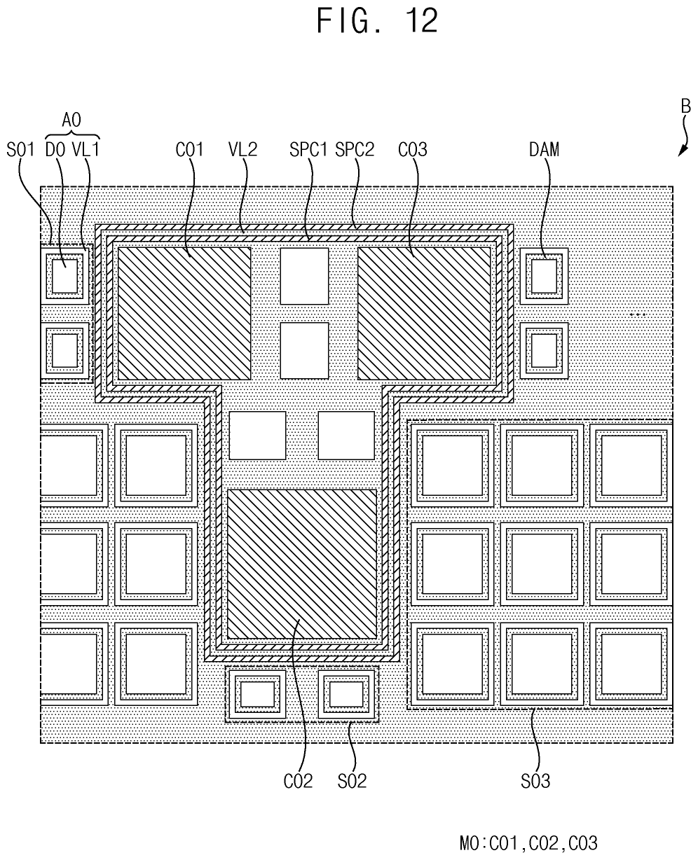

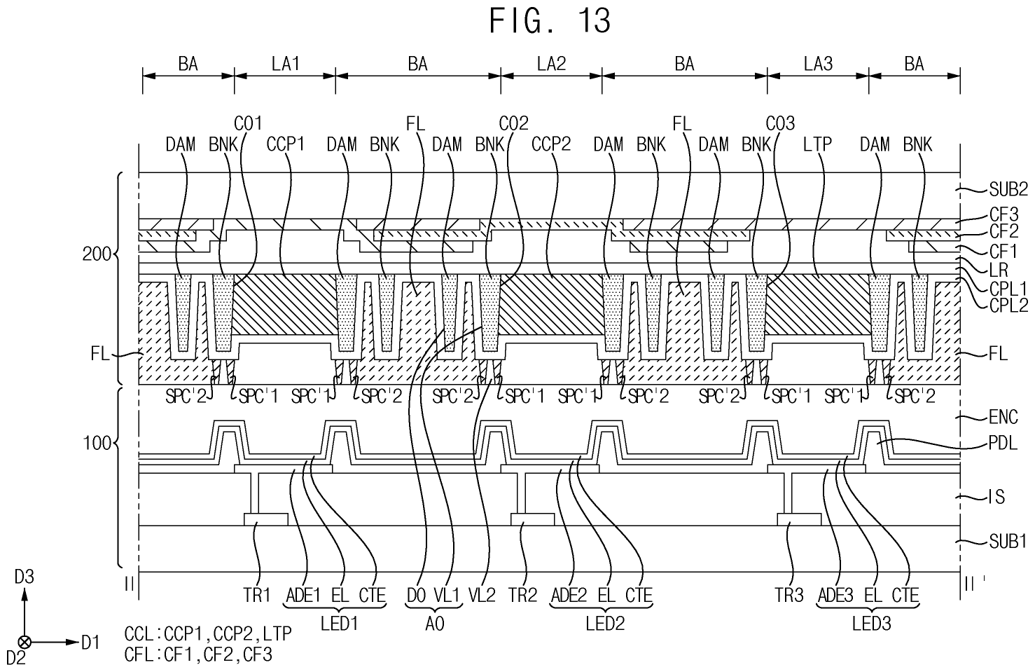

FIG. 10 is a plan view illustrating a display device according to one or more other embodiments. FIG. 11 is a plan view illustrating a color conversion substrate included in the display device of FIG. 10. FIG. 12 is an enlarged view illustrating an enlarged area B of FIG. 11. FIG. 13 is a cross-sectional view taken along the line III-III′ of FIG. 10.

Here, FIG. 10 may correspond to the plan view of FIG. 3, FIG. 11 may correspond to the plan view of FIG. 4, and FIG. 13 may correspond to the cross-sectional view of FIG. 6.

Hereinafter, a display device according to one or more other embodiments will be described with reference to FIGS. 1, 2, and 10 to 13. In the following description, differences from the display device described with reference to FIGS. 3 to 6 will be mainly described, and overlapping descriptions will be omitted or simplified.

Referring to FIGS. 1, 2, and 10 to 13, the first spacer SPC1 may surround the main opening area MO. That is, the first spacer SPC1 may surround the first to third color conversion openings CO1, CO2, and CO3, which are included in one of the main opening area MO, collectively.

In this case, the dam structure DAM may not be located in those of the auxiliary openings AO that are surrounded by the first spacer SPC1.

Similarly, the second spacer SPC2 may surround the first spacer SPC1. Accordingly, the second spacer SPC2 may surround the main opening area MO. That is, the second spacer SPC2 may surround the first to third color conversion openings CO1, CO2, and CO3 included in one of main opening area MO at once.

Also, the second valley part VL2 may be defined from a side surface of the first spacer SPC1 and a side surface the second spacer SPC2. For example, an outer surface of the first spacer SPC1 and an inner surface of the second spacer SPC2 adjacent to the outer surface of the first spacer SPC1 may define the second valley part VL2.

In other words, the first spacer SPC1 and the second spacer SPC2 may define the second valley part VL2 having a ring shape, and the second valley part VL2 may surround the main opening area MO. That is, the second valley part VL2 may surround the first to third color conversion openings CO1, CO2, and CO3 included in one of main opening area MO at once.

The first spacer SPC1 and/or the second spacer SPC2 may reduce or prevent the likelihood of the filling material overflowing into the main opening area MO. In other words, the first spacer SPC1 and/or the second spacer SPC2 may reduce or prevent the likelihood of the filling material from overflowing into the first to third color conversion openings CO1, CO2, and CO3 included in one of the main opening area MO at once. In other words, the filling material may not be applied to the first to third light-emitting areas LA1, LA2, and LA3 by the first spacer SPC1 and/or the second spacer SPC2.

Accordingly, the filling layer FL may be spaced apart from the first to third light-emitting areas LA1, LA2, and LA3 in a plan view and may overlap at least a portion of the light-blocking area BA. In other words, the filling layer FL may not overlap the first to third light-emitting areas LA1, LA2, and LA3 in a plan view.

For example, the filling layer FL may be spaced apart from the main opening area MO of the bank BNK in a plan view. For example, the filling layer FL may surround the main opening area MO. Accordingly, the filling layer FL may be spaced apart from the color conversion layer CCL in a plan view.

The filling layer FL may not be located in the auxiliary openings AO surrounded by the first spacer SPC1 among the auxiliary openings AO. That is, the filling material may not be applied in the auxiliary openings AO surrounded by the first spacer SPC1 among the auxiliary openings AO.

An area where the filling layer FL is located may be further reduced. Accordingly, display characteristics of the display device 1000 may be further improved.

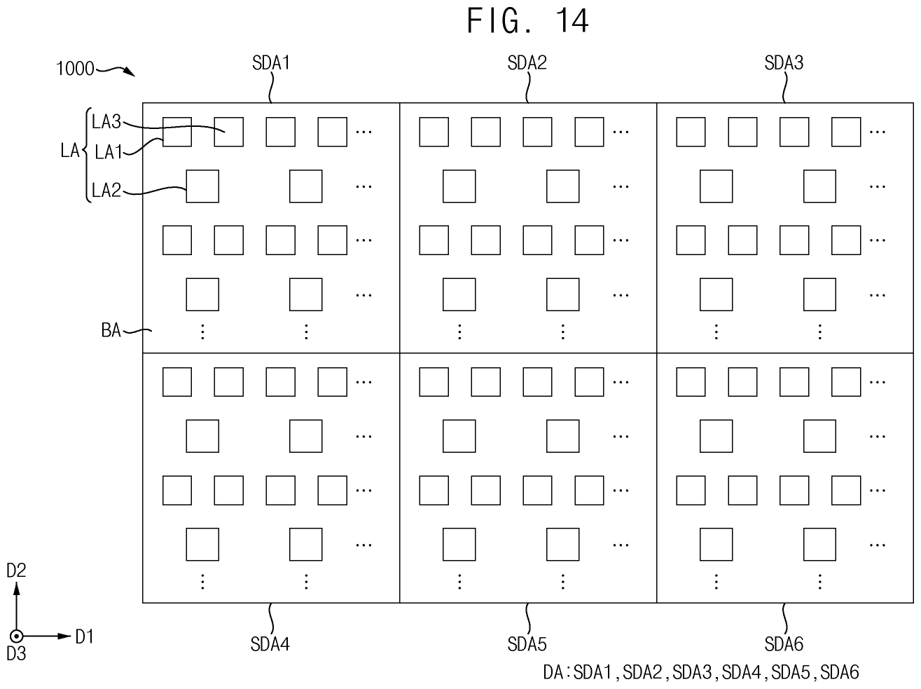

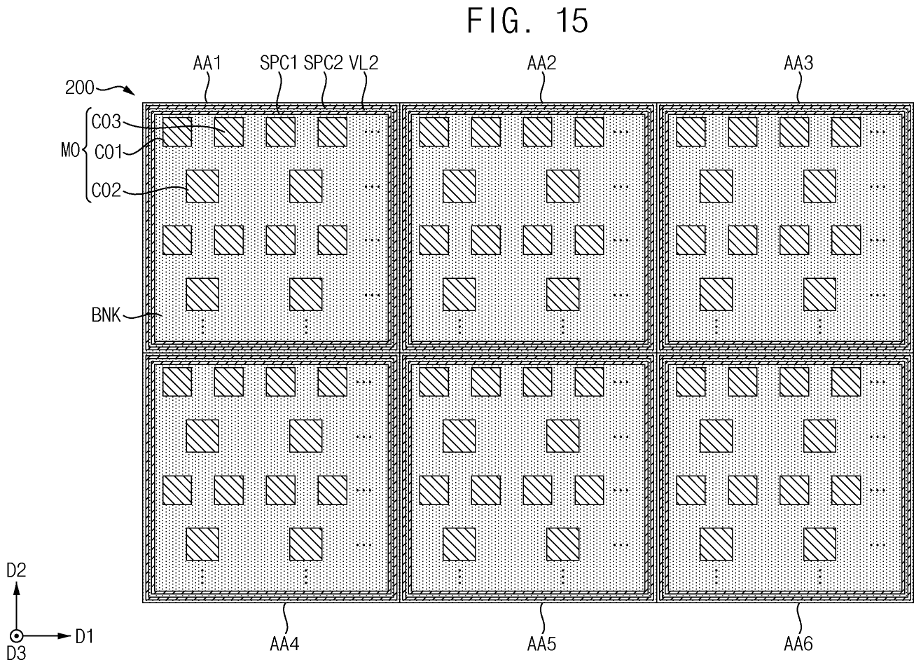

FIG. 14 is a plan view illustrating a display device according to still one or more other embodiments of the present disclosure. FIG. 15 is a plan view illustrating a color conversion substrate included in the display device of FIG. 14.

Here, FIG. 14 may correspond to the plan view of FIG. 3, and FIG. 15 may correspond to the plan view of FIG. 4. Hereinafter, a display device according to one or more other embodiments of the present disclosure will be described with reference to FIGS. 1, 2, 14, and 15. In the following description, differences from the display device described with reference to FIGS. 3 to 6 will be mainly described, and overlapping descriptions will be omitted or simplified.

Referring to FIGS. 1, 2, 14, and 15, the display area DA may include sub display areas including at least two or more of the light-emitting areas LA. For example, the display area DA may be divided into six sub display areas SDA1, SDA2, SDA3, SDA4, SDA5, and SDA6 composed of two rows and three columns. However, the present disclosure is not necessarily limited thereto, and the display area DA may be divided into four or fewer sub display areas or eight or more sub display areas forming rows and columns. Each of the sub display areas SDA1, SDA2, SDA3, SDA4, SDA5, and SDA6 of the display device 1000 may include the light-emitting area LA and the light-blocking area BA.

In one or more embodiments, the bank BNK may include at least two or more active areas including the main opening area MO. For example, the bank BNK may be divided into six active areas AA1, AA2, AA3, AA4, AA5, and AA6 composed of two rows and three columns. Here, the active areas AA1, AA2, AA3, AA4, AA5, and AA6 may correspond to the sub display areas SDA1, SDA2, SDA3, SDA4, SDA5, and SDA6 of FIG. 10, respectively. However, the present disclosure is not necessarily limited thereto, and the bank BNK may be divided into four or fewer active areas or eight or more active areas forming rows and columns.

In one or more embodiments, the first spacer SPC1 may surround each of the active areas AA1, AA2, AA3, AA4, AA5, and AA6 individually. That is, the first spacer SPC1 may surround the main opening area MO including two or more color conversion openings in one of the active areas. In other words, the first spacer SPC1 may surround, collectively, the first to third color conversion openings CO1, CO2, and CO3 included in one of the active areas.

The dam structure (DAM, see FIG. 4) may be omitted from the auxiliary openings (AO, see FIG. 4) surrounded by the first spacer SPC1 among the auxiliary openings AO.

Similarly, the second spacer SPC2 may surround each of the active areas AA1, AA2, AA3, AA4, AA5, and AA6. That is, the second spacer SPC2 may surround the main opening area MO including two or more conversion openings in one of the active areas. In other words, the second spacer SPC2 may surround the first to third color conversion openings CO1, CO2, and CO3 included in one of the active areas.

Also, a side surface of the first spacer SPC1 and a side surface of the second spacer SPC2 may define a second valley part VL2. For example, an outer surface of the first spacer SPC1, and an inner surface of the second spacer SPC2 that is adjacent to the outer surface of the first spacer SPC1, may define the second valley part VL2.

In other words, the first spacer SPC1 and the second spacer SPC2 may define the second valley part VL2 having a ring shape, and the second valley part VL2 may surround each of the active areas AA1, AA2, AA3, AA4, AA5, and AA6. That is, the second valley part VL2 may surround the main opening area MO including two or more color conversion openings in one of the active areas at once. In other words, the second valley part VL2 may surround the first to third color conversion openings CO1, CO2, and CO3 that are included in one of the active areas.

The first spacer SPC1 and/or the second spacer SPC2 may reduce or prevent the likelihood of the filling material overflowing into the active areas AA1, AA2, AA3, AA4, AA5, and AA6. In other words, the first spacer SPC1 and/or the second spacer SPC2 may reduce or prevent the likelihood of the filling material overflowing into the main opening area MO. That is, the first spacer SPC1 and/or the second spacer SPC2 may reduce or prevent the likelihood of the filling material from overflowing into the first to third color conversion openings CO1, CO2, and CO3 included in one of the main opening area MO at once. In other words, the filling material may not be applied to the first to third light-emitting areas LA1, LA2, and LA3 due to the first spacer SPC1 and/or the second spacer SPC2.

Accordingly, the filling layer FL may be spaced apart from the first to third light-emitting areas LA1, LA2, and LA3 in a plan view, and may overlap at least a portion of the light-blocking area BA. In other words, the filling layer FL may not overlap the first to third light-emitting areas LA1, LA2, and LA3 in a plan view.

For example, the filling layer FL may be spaced apart from the main opening area MO of the bank BNK in a plan view. The filling layer FL may surround the main opening area MO. Accordingly, the filling layer FL may be spaced apart from the color conversion layer CCL in a plan view.

In one or more embodiments, the filling layer FL may be omitted from the auxiliary openings (AO, see FIG. 4) surrounded by the first spacer SPC1 among the auxiliary openings AO. That is, the filling material may not be applied in the auxiliary openings AO surrounded by the first spacer SPC1 among the auxiliary openings AO.

An area where the filling layer FL is located may be further reduced. Accordingly, display characteristics of the display device 1000 may be further improved.

According to embodiments, the display device 1000 may include the array substrate 100, and may include the color conversion substrate 200 located on the array substrate 100. In addition, the color conversion substrate 200 may include the bank BNK including the main opening area MO including the first to third color conversion openings CO1, CO2, and CO3, and including the sub opening area including the auxiliary openings AO. In addition, the color conversion substrate 200 may include the dam structure DAM defining the dam opening DO that is located in the auxiliary opening AO, the first spacer SPC1 located on the bank BNK and surrounding the first to third color conversion openings CO1, CO2, and CO3, and the second spacer SPC2 located on the bank BNK and surrounding the first spacer SPC1.

Accordingly, in the color conversion substrate 200, the first valley part VL1 may be defined from the side surface of the dam structure DAM and the side surface of the bank BNK, and the second valley part VL2 may be defined from the side surface of the first spacer SPC1 and the side surface of the second spacer SPC2.

Therefore, when the filling material is applied to form the filling layer FL between the array substrate 100 and the color conversion substrate 200, the dam structure DAM, the first spacer SPC1, and the second spacer SPC2 may reduce or prevent the likelihood of the filling material overflowing into the first to third color conversion openings CO1, CO2, and CO3, which are neighboring. In other words, the filling layer FL may be selectively located in the dam opening DO, the first valley part VL1 and/or the second valley part VL2. Accordingly, the filling layer FL may be spaced apart from the first to third color conversion openings CO1, CO2, and CO3 in a plan view. In other words, the filling layer FL may be spaced apart from the light-emitting area LA in a plan view.

Accordingly, a phenomenon in which spots are generated in the light-emitting area LA due to scattering of the filling layer FL may be reduced or prevented. Also, because the light emitted from the array substrate 100 does not pass through the filling layer FL, luminous efficiency of the display device 1000 may be improved. Accordingly, display characteristics of the display device 1000 may be improved.

The present disclosure should not be construed as being limited to the embodiments set forth herein. Rather, these embodiments are provided so that this disclosure will be thorough and complete and will fully convey the concept of the present disclosure to those skilled in the art.

While the present disclosure has been particularly shown and described with reference to embodiments thereof, it will be understood by those of ordinary skill in the art that various changes in form and details may be made therein without departing from the spirit or scope of the present disclosure as defined by the following claims, with functional equivalents thereof to be included therein.

What is claimed is:

1. A color conversion substrate comprising:
a bank defining a main opening area comprising a first color conversion opening, a second color conversion opening, and a third color conversion opening, and defining a sub opening area comprising an auxiliary opening;
a color conversion layer in the first, second, and third color conversion openings, and comprising color conversion particles;
a dam structure in the auxiliary opening, and defining a dam opening;
a first spacer above the bank, having a closed loop shape, and surrounding the first color conversion opening, the second color conversion opening, and the third color conversion opening in plan view; and
a second spacer above the bank, having a closed loop shape, and surrounding the first spacer in plan view.

2. The color conversion substrate of claim 1, wherein the first spacer and the second spacer comprise a same material.

3. The color conversion substrate of claim 1, wherein the dam structure and the bank comprise a same material.

4. The color conversion substrate of claim 3, wherein the dam structure has a closed loop shape.

5. The color conversion substrate of claim 4, wherein a side surface of the dam structure and a side surface of the bank define a first valley part surrounding the dam opening in plan view.

6. The color conversion substrate of claim 1, wherein a side surface of the first spacer and a side surface of the second spacer define a second valley part in plan view.

7. The color conversion substrate of claim 6, wherein the first spacer surrounds each of the first color conversion opening, the second color conversion opening, and the third color conversion opening in plan view, and
wherein the second valley part surrounds each of the first color conversion opening, the second color conversion opening, and the third color conversion opening in plan view.

8. The color conversion substrate of claim 6, wherein the first spacer surrounds the main opening area in plan view, and
wherein the second valley part surrounds the main opening area in plan view.

9. The color conversion substrate of claim 6, wherein the bank comprises an active area comprising the main opening area,
wherein the first spacer surrounds the active area in plan view, and
wherein the second valley part surrounds the active area in plan view.

10. The color conversion substrate of claim 1, wherein the color conversion layer comprises a first color conversion part, a second color conversion part, and a light transmission part in the first, second, and third color conversion openings, respectively.

11. A display device comprising:
a bank defining a main opening area comprising a first color conversion opening, a second color conversion opening, and a third color conversion opening, and defining a sub opening area comprising an auxiliary opening;
a color conversion layer in the first, second, and third color conversion openings, and comprising color conversion particles;
a dam structure in the auxiliary opening, and defining a dam opening;
a first spacer above the bank, having a closed loop shape, and surrounding the first color conversion opening, the second color conversion opening, and the third color conversion opening in plan view;
a second spacer above the bank, having a closed loop shape, and surrounding the first spacer;
an array substrate below the color conversion layer, and comprising light-emitting elements overlapping the first, second, and third color conversion openings, respectively; and
a filling layer above the array substrate, and spaced apart from the first, second, and third color conversion openings in a plan view.

12. The display device of claim 11, wherein the filling layer is spaced apart from the color conversion layer in plan view.

13. The display device of claim 11, wherein at least a portion of the filling layer is in the dam opening.

14. The display device of claim 11, wherein a side surface of the dam structure and a side surface of the bank define a first valley part, and
wherein at least a portion of the filling layer is in the first valley part.

15. The display device of claim 11, wherein a side surface of the first spacer and a side surface of the second spacer define a second valley part, and
wherein at least a portion of the filling layer is in the second valley part.

16. The display device of claim 15, wherein the first spacer surrounds each of the first color conversion opening, the second color conversion opening, and the third color conversion opening in plan view, and
wherein the filling layer surrounds each of the first color conversion opening, the second color conversion opening, and the third color conversion opening in plan view.

17. The display device of claim 15, wherein the first spacer surrounds the main opening area in plan view, and
wherein the filling layer surrounds the main opening area in plan view.

18. The display device of claim 15, wherein the bank comprises an active area comprising the main opening area,
wherein the first spacer surrounds the active area in plan view, and
wherein the filling layer surrounds the active area in plan view.

19. The display device of claim 11, wherein the filling layer comprises a light-blocking material.

20. The display device of claim 11, wherein the first color conversion opening and the third color conversion opening are repeatedly arranged in a first row,
wherein the second color conversion opening is repeatedly arranged in a second row, and
wherein the sub opening area is between the first, second, and third color conversion openings.
